(19) United States
(12) Patent Application Publication
(10) Pub. No.: US 2011/0192984 A1
(43) Pub. Date: Aug. 11, 2011

(54) METHOD AND EQUIPMENT FOR PRODUCING DRIFT DETECTORS

(75) Inventors: Mario Urdaneta, Berwyn Heights, MD (US); Pavel Stepanov, North Potomac, MD (US); Irving WEINBERG, Bethesda, MD (US)

(73) Assignee: WEINBERG MEDICAL PHYSICS LLC, Bethesda, MD (US)

(21) Appl. No.: 13/022,254

(22) Filed: Feb. 7, 2011

Related U.S. Application Data
(60) Provisional application No. 61/302,628, filed on Feb. 9, 2010.

(51) Int. Cl. G01T 1/24; H01L 31/18

(52) U.S. Cl. 250/370.09; 438/56; 257/E31.119

(57) ABSTRACT

Silicon drift detectors are produced for location and energy measurement as well as spectroscopic applications by depositing a single high quality dielectric film followed by deposition of at least one low quality dielectric film.

### CROSS-REFERENCE TO RELATED APPLICATION(S)

The present application claims the benefit of priority to Provisional Patent Application No. 61/302,628 filed Feb. 9, 2010, the contents of which are incorporated herein by reference in their entirety.

### FIELD OF THE INVENTION

Disclosed embodiments are directed, generally, to a method of producing silicon drift detectors in fabricated materials.

### SUMMARY

The following presents a simplified summary in order to provide a basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to the more detailed description below.

In accordance with at least one disclosed embodiment, a method is provided for producing silicon drift detectors for various applications including, location and energy measurement, spectroscopic applications, etc.

### BRIEF DESCRIPTION OF THE DRAWINGS

A more compete understanding of the present invention and the utility thereof may be acquired by referring to the following description in consideration of the accompanying drawings, in which like reference numbers indicate like features, and wherein:

FIG. 1 illustrates a simplified diagram of a silicon drift detector designed in accordance with the disclosed embodiments;

FIG. 2 provides an illustrative representation of a silicon drift detector designed in accordance with the disclosed embodiment during ion implantation in the case that the high quality dielectric film is not etched; and

FIG. 3 provides an illustrative representation of a method provided in accordance with the disclosed embodiments.

### DETAILED DESCRIPTION

The description of specific embodiments is not intended to be limiting of the present invention. To the contrary, those skilled in the art should appreciate that there are numerous variations and equivalents that may be employed without departing from the scope of the present invention. Those equivalents and variations are intended to be encompassed by the present invention.

In the following description of various invention embodiments, reference is made to the accompanying drawings, which form a part hereof, and in which is shown, by way of illustration, various embodiments in which the invention may be practiced. It is to be understood that other embodiments may be utilized and structural and functional modifications may be made without departing from the scope and spirit of the present invention.

Moreover, it should be understood that various connections are set forth between elements in the following description; however, these connections in general, and, unless otherwise specified, may be either direct or indirect, either permanent or transitory, and either dedicated or shared, and that this specification is not intended to be limiting in this respect.

Compton cameras are a class of radiation detection instruments which can provide images of radiation sources. Compton cameras operate by measuring the energy loss in a scatter medium from incident gamma-ray photons. The energy loss occurs as the incident photon transfers some of its energy to an electron in the scattering medium. Using the Klein-Nishina formula, it is possible to calculate the angle of the incident photon with respect to the scattered photon by measuring the energy loss in the scattering medium assuming that the initial energy of the photon (prior to scattering) is known or can be measured. In a Compton camera, the scattered photon comes to rest in a separate absorbing medium where the energy left in the photon after scattering is measured. By knowing the incident angle information, and the spatial locations of the interactions in both the scatter and absorbing media, it is possible to estimate the direction of photon's source as being on a cone of possible directions. If the directions of electron tracks produced during the scattering event are measured, the estimate of the photon's source can be improved to an arc on the cone. The current invention is intended to facilitate the production of scattering detector components that are particularly effective for the construction of Compton cameras with electron-tracking capability.

Silicon is a preferred material as a scattering medium for Compton-type cameras. The low atomic number of silicon reduces Doppler-broadening that can compromise the performance of Compton cameras. This invention describes methods for fabricating silicon detectors optimized for Compton camera operation. Preferably, the silicon detector is in the configuration called “silicon drift detector”, because of reasons described below. A silicon drift detector is defined for the purposes of this invention as a detector containing at least two layers of silicon, each of which has different electrical conductivity. For the purposes of this invention, a silicon drift detector includes other multi-layer detector variants which have different names, including controlled-drift detector, silicon drift detector with channel-stops. The methods embodied in this invention do not apply only to silicon drift detectors, but can apply to other semiconductor-type radiation detectors or drift detectors using semiconductors other than silicon. The methods embodied in the current invention, although specified as preferable for a device with at least two layers of silicon, are likely to apply in an alternative embodiment to other devices with only one layer.

Silicon drift detectors can provide high accuracy in estimating the energy of scattered radiation (i.e., energy resolution) at room temperature or with minimal cooling. See, Castoldi et al., U.S. Pat. No. 6,249,033, 2001. According to the Klein-Nishina equation, accurate measurement of energy loss during the radiation scatter is important in estimating the scattering angle of the incident photon. High energy resolution is achievable with silicon drift detectors because ionization electrons are collected (under the influence of shaped electric field) onto small low-capacitance anode. The low capacitance of the anode and the low leakage current of highly-purified silicon contribute to the excellent energy resolution exhibited by silicon drift detectors at room temperature or with minimal cooling.

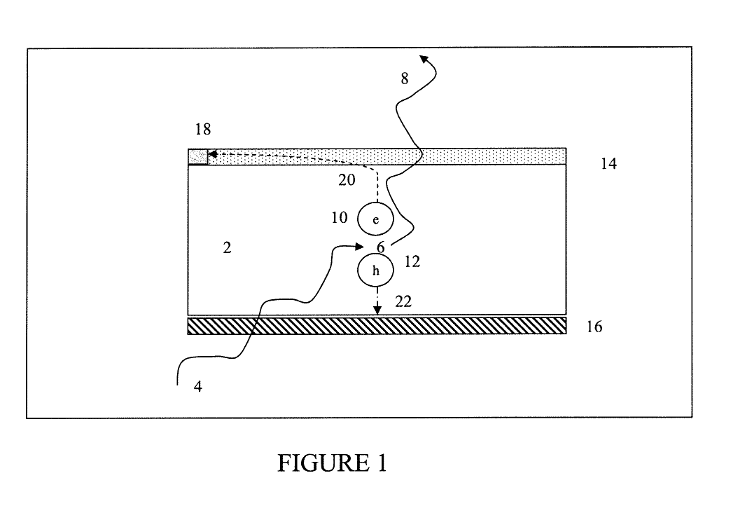

A simplified diagram of a silicon drift detector is shown in FIG. 1. As seen in FIG. 1, charge pairs created by incident radiation are separated, with the electrons drifting rapidly towards the epitaxial layer, while holes migrate rapidly towards the cathode. Once the electrons reach the epitaxial layer, they drift slowly towards one or more anodes. Preferably, the electron drift trajectories can be separated from one another by electro-potential bathers, known as channel stops. Channel stops have been shown to improve the spatial resolution of silicon drift detectors due to reduction of electron cloud diffusion. See, Castoldi, Rehak, and Holl, “Signal sharing in multilinear drift detectors: design and experimental characterization”, IEEE Trans. Nuc. Sci., 44(2), 1997.

FIG. 1 depicts a cross-section of a silicon drift detector between channel stops, and as a result does not illustrate channel stops. Silicon drift detectors can be used to measure the energy of incident radiation in spectroscopic applications, and can also provide spatial information as to the location of the incident radiation.

In accordance with at least one disclosed embodiment, a method is provided for producing silicon drift detectors for location and energy measurement; however, it should be understood that the inventive concept is not limited to such an implementation and may be utilized to provide methodologies that can also be used to produce silicon drift detectors for spectroscopic applications (i.e., which do not provide location information). This is because the location of the incident radiation may be derived from measurements of the arrival time of electrons at the anode and comparing these measurements to other measurements of the arrival time of the holes at the cathode.

Furthermore, it should be understood that at least one disclosed embodiment provides methodologies for deriving the location of the incident radiation by comparing the arrival time of electrons at the anode to a separate measurement of the incident radiation's arrival time (i.e., at a separate device acting as an absorbing medium). Moreover, other applications and implementations are also available to derive the location of the incident radiation.

A silicon drift detector provides an elegant methodology for achieving excellent spatial resolution because relatively few readout channels are needed as compared to other devices (for example, charged-coupled devices). With the excellent energy resolution afforded by a silicon drift detector, it is possible to locate the absorbing medium of a Compton camera in close proximity (i.e., less than 15 cm) to the scattering medium. This also achieves compactness and improves count efficiency.

If the channel stops are separated by less distance than the length of the recoil electron's track, it is possible to estimate the direction and/or length of the recoil electron track. Other methods may be employed to estimate the direction and/or length of the recoil electron track. Moreover, as described above, the estimation of the electron track direction significantly improves the performance of the Compton camera.

Returning to FIG. 1, that figure illustrates a schematic representation of a silicon drift detector with an epitaxial layer. As further shown in that figure, a bulk silicon material 2 is traversed by an incident gamma-ray photon 4. In at least one embodiment, gamma-ray photon 4 may lose some of its energy as a result of a scattering interaction at a location 6, causing electrons and holes to be formed in the bulk silicon material 2. The scattered photon 8 may continue on, albeit at reduced energy and at an angle from the incident direction vector. Thus, a representative electron and hole are shown as 10 and 12 respectively.

Under the influence of applied electric fields (not shown) the electrons and holes travel in opposite directions, towards the epitaxial layer 14 and the cathode electrode layer 16, respectively, producing an electrical signal on the cathode 16. Upon arriving at the epitaxial layer 14, and under the influence of electric fields (not shown), the electrons travel along the epitaxial layer 14 towards an anode 18, where they can be collected for measurement. The path of the representative electron 8 is represented as 20, and the path of the holes as 22.

The speed of travel of the electrons in epitaxial layer 14 may be much less than the speed of the electrons and holes in the bulk layer 2. The period of time that the representative electron 10 spends in the epitaxial layer 14 may be dependent on the distance from the location of interaction 6 to the anode 18; this period of time may be much greater than the time it takes for electron 10 and hole 12 to reach the epitaxial layer 14 and the cathode layer 16. Accordingly, it is possible to estimate the location 6 by measuring the time delay between the signal on the anode 18 and signal on the cathode 16.

In accordance with at least one embodiment, it may be desirable for an apparatus to synchronize the detection of radiation in both the scatter and absorbing components of the Compton camera to generate better data (e.g., to reduce/eliminate background and/or random events) for Compton camera reconstruction. To achieve this synchronization, it may be useful to utilize a trigger pulse generated by the silicon drift detector when it scatters radiation. Such a silicon drift detector can provide a trigger when the bulk silicon scattering layer is coated on one side with an epitaxial silicon layer that has a different conductivity than the bulk layer, and when an electrode is provided (on the side of the detector opposite from the anode to serve as a cathode), as illustrated in FIG. 1.

It should be understood that contaminants and their spread in the silicon reduce electron lifetime due to recombination and trapping. The reduction in lifetime can compromise the performance of silicon drift detectors in Compton cameras and other applications. Thus, to reduce contamination, silicon drift detectors can be fabricated using ultra-clean methods, for example, involving special cleaning procedures after every step. See, G. Thesis: C. Guazzoni, “The controlled-drift detector: a new X-ray imaging detector”, PhD thesis, Politecnico di Milano, Italy, 1999. In addition to such ultra-clean methods, methods for fabricating silicon drift detectors can include the requirement for high temperature processes (including annealing and dielectric deposition). Guazzoni specified a temperature of 900 degrees Centigrade for the disclosed processes, and Sonsky has specified a minimum temperature of 380 degrees Centigrade for dielectric deposition. See, J. Sonsky, “Multi-anode linear SDDs for high-resolution X-ray spectroscopy”, dissertation, Technische Universiteit Delft, 2002.

However, the current inventive concept may be utilized to provide methodologies for fabricating drift detectors that minimize the need for ultra-clean environments. This may be provided for silicon drift detectors with a silicon epitaxial layer.

More specifically, a necessary process in the fabrication of silicon drift detectors is the deposition of one or more dielectric films. Thus, in accordance with at least one disclosed embodiment, a first operation involves deposition of a single high quality dielectric film onto the silicon. It should be understood that the term “silicon” refers to both the silicon bulk of the detector and the silicon epitaxial layer deposited on it. Moreover, it should be understood that the term “silicon bulk” includes non-epitaxial portions of a silicon wafer.

Furthermore, the term “high quality,” as it describes dielectric film, refers to film lacking defects or having low porosity, such that the high quality dielectric film can act as a barrier to diffusion of contaminants. Thus, an example of a high quality dielectric film is a film produced by dry thermal oxidation of silicon.

A high quality dielectric film deposited atop the silicon is necessary to electrically isolate different parts of the device at relatively high voltage differentials typically applied to silicon drift detectors. Typical voltage differentials used for silicon drift detectors in high energy physics applications may be several hundred volts.

Following deposition of the single high quality dielectric film, a plurality of dielectric films are deposited at low temperatures. For the purposes of this invention, the term “low temperature” means a temperature less than 350 degree Centigrade; films deposited in this way may be considered “low quality” dielectric films.

In accordance with the at least one disclosed embodiment, deposition of the single high quality dielectric film may precede the deposition of the plurality of dielectric films at low temperatures.

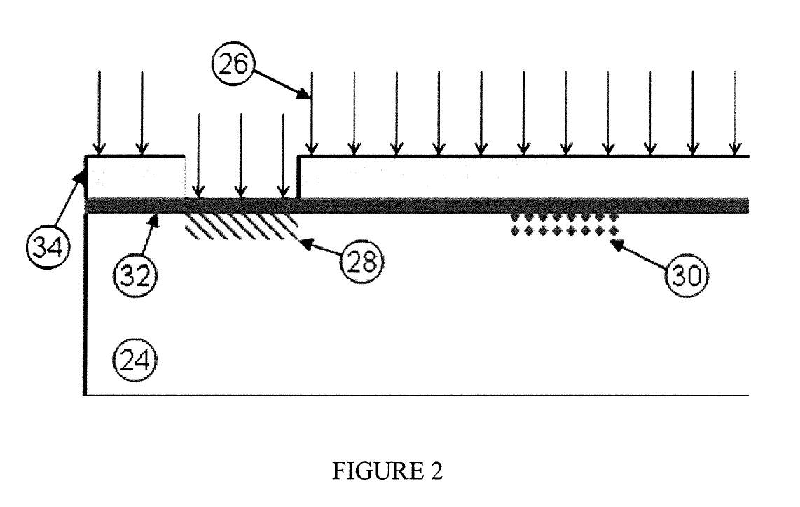

The deposition of the plurality of dielectric films at low temperatures is performed as part of the fabrication of silicon drift detectors. The deposition of the single high quality dielectric film may potentially only be applied one time in the fabrication process, while the deposition of the plurality of dielectric films at low temperatures may potentially be repeated multiple times, as illustrated in FIG. 2.

Conventionally, Guazzoni disclosed deposition of high quality dielectric films multiple times, unlike the single application in the present inventive concept. Furthermore, Sonsky disclosed deposition of a single high quality dielectric film on a silicon detector substrate (i.e., where radiation is absorbed), but not on an epitaxial layer (i.e., to drift electrons to the anode) as in the presently disclosed embodiments. Furthermore, in Sonsky, the deposed high quality dielectric film was thick (i.e., 400 nm), in order to provide sufficient thickness for blocking ions delivered during subsequent ion implantation steps. It may be preferable, in some implementations, for the single high quality dielectric film to be thin, e.g., less than 100 nanometers.

Additionally, Sonsky disclosed etching the high quality dielectric film in regions where ions were implanted. By contrast, in accordance with the presently disclosed inventive concept, it is not necessary to etch the high quality dielectric film prior to ion implantation. The relaxation of the conventional requirement for etching is provided as a result of the thinness of the high quality dielectric film, since subsequent low-quality dielectric films provide sufficient overall thickness as required for subsequent ion implantation steps.

Thus, in accordance with at least one disclosed embodiment, the deposited high quality dielectric film is only etched once, after all ion implantation steps and prior to the deposition of electrical contacts. FIG. 2 illustrates this preferred embodiment of the invention. FIG. 2 provides a representation of the silicon drift detector during ion implantation in the case that the high quality dielectric film is not etched. The silicon 24 is undergoing ion implantation 26 in order to create a doped region 28. A previously-doped region 30 is shown for illustrative purposes. The high quality dielectric film 32 is thin enough for ions accelerated at energy levels typically used in the fabrication of drift detectors (e.g., >40 keV) to pass through the high quality dielectric film. The high quality dielectric film 32 also impedes the diffusion of contaminants into the silicon. To ensure that the accelerated ions, which impinge upon the entire silicon substrate, do not reach the silicon in regions other than 28, it is necessary that a thick layer (i.e., of low quality dielectric film 34 is in place). The doped region 30 is not affected by the accelerated ions either, due to the protective effect of the low quality dielectric film 34.

In an alternative embodiment, the deposition of the single high quality dielectric film may be upon the silicon substrate directly, without the intervening epitaxial layer.

Various advantages are provided as a result of implementing the presently disclosed embodiments. For example, using the presently disclosed embodiments provides eliminates the need for ultra-clean processes that are conventionally required for high-temperature dielectric film deposition. This is because the diffusion barrier created during deposition of the high-quality dielectric film actually protects the silicon substrate and/or silicon epitaxial layer from contamination during subsequent processes. The low-temperature dielectric film deposition further reduces the likelihood of contamination of the silicon substrate and/or silicon epitaxial layer. Thus, the contributions of both depositions stages actually add synergistically to reduce contamination of the silicon substrate and/or silicon epitaxial layer.

Additionally, disclosed embodiments including only a single application of a high quality dielectric film in the fabrication of the silicon drift detector (and preferably prior to subsequent deposition operations) has the advantage of eliminating the need for high-temperature annealing of dielectric films deposited in subsequent operation stages. As described above, the use of high temperature processes might otherwise add to unwanted contamination of the epitaxial and/or substrate layers due to diffusion.

Differences between the presently disclosed methodologies and the prior art, and the advantages provided by the presently disclosed embodiments may be further illustrated through the calculation of a Figure Of Merit (FOM) for fabrication processes of semiconductor radiation detectors. The diffusion of contaminants obeys an exponential relationship with temperature, and a linear relationship to the square root of the exposure time, as shown below:

$$FOM = {e}^{- \frac{1}{T}} \cdot \sqrt{t} \qquad ( 1 )$$

where T is the process temperature measured in degrees Kelvin, t is the process time in seconds. For illustrative purposes, the highest value of the FOMs for Sonsky's fabrication may be estimated to be 260, for Guazzoni's fabrication the highest value of the FOM may be roughly estimated at 260, whereas, for the methodologies of the present disclosure provide an estimated highest value of the FOM at 90. At the same time, the sum of the FOMs for all of Sonsky's fabrication operations may be estimated to be 480, for Guazzoni's fabrication the total may be estimated at 520, whereas for the methods of the presently disclosed embodiments, the FOM may be estimated at 220. Thus, it should be appreciated that quantities and qualities other than the FOM may be optimized or affected by utilization of the presently disclosed embodiments.

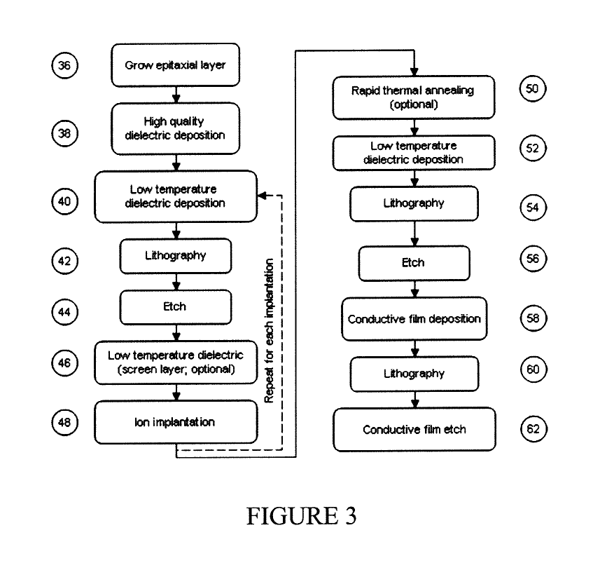

One illustrative example of the fabrication sequence provided in accordance with the disclosed embodiments is shown in FIG. 3. As shown in FIG. 3, the method begins at 36, at which an optional epitaxial layer is grown on a wafer that serves as the device substrate. Alternatively, the sequence can begin at 36 without the need for the epitaxial layer. The process then continues to 38, at which a dielectric film of high quality is grown through oxidation of the semiconductor (e.g., through dry oxidation). Subsequently, the process proceeds to 40, at which a low quality dielectric film is deposited at low temperature (<350° C.). Lithography is used to pattern a masking material on top of the low quality dielectric film at 42.

Subsequently, at 44, etching is used to transfer the lithographic pattern onto the low quality dielectric film. Optionally, at 46, another low quality dielectric film may be deposited to act as a screen layer for mitigation of subsequent ion implantation damage. At 48, ions are implanted in order to dope the silicon. Operations performed at 40-48 may be repeated multiple times in order to produce regions of different doping characteristics. Rapid thermal annealing may be performed at 50 in order to activate the dopants implanted in the semiconductor. A low quality dielectric film may be deposited at low temperature at 52.

Subsequently, at 54, lithography may be used to pattern a masking material on top of the low quality dielectric film. Etching may be used, at 56, to transfer the lithographic pattern onto the low quality dielectric film and high quality dielectric film with the goal of exposing the epitaxial layer or, in the case that an epitaxial layer was not deposited, the bulk silicon. The high and low quality dielectric films can be etched at the same time or in separate processes. Subsequently, at 58, a conductive film acting as an electrode is deposited on the low quality dielectric film and the epitaxial layer (if the epitaxial layer had been previously deposited) or bulk silicon (if the epitaxial layer had not been previously deposited). Lithography may then be used at 60 to pattern a masking material on top of the conductive film. Subsequently, at 62, etching is used to transfer the lithographic pattern onto the conductive film.

While this invention has been described in conjunction with the specific embodiments outlined above, it is evident that many alternatives, modifications and variations will be apparent to those skilled in the art. Accordingly, the various embodiments of the invention, as set forth above, are intended to be illustrative, not limiting. Various changes may be made without departing from the spirit and scope of the invention.

For example, although the above disclosure describes the fabrication of silicon drift detectors, it should be understood that the drift detectors may be composed of materials other than silicon. Although the above invention describes the measurement of the direction and energy of gamma rays, it is understood that other forms of radiation will also work, including x-rays, charged particles (for example, electrons, positrons, protons, muons), neutral particles (for example, neutrons, pions) and ions (for example, C⁶⁺) and particle beams.

Additionally, it should be understood that the functionality described in connection with various described operations of various embodiments may be combined or separated from one another in such a way that the process of the invention is somewhat different than what is expressly disclosed herein. Moreover, it should be understood that, unless otherwise specified, there is no essential requirement that methodology operations be performed in the illustrated order; therefore, one of ordinary skill in the art would recognize that some operations may be performed in one or more alternative order and/or simultaneously.

Various components of the invention may be provided in alternative combinations operated by, under the control of or on the behalf of various different entities or individuals.

Further, it should be understood that, in accordance with at least one embodiment of the invention, system components may be implemented together or separately and there may be one or more of any or all of the disclosed system components. Further, system components may be either dedicated systems or such functionality may be implemented as virtual systems implemented on general purpose equipment via software implementations.

Although the utility of various invention embodiments has been described in connection with the distribution of promotional content, it should be understood that distributed information is not limited to promotional content but may also or alternatively include non-promotional material.

As a result, it will be apparent for those skilled in the art that the illustrative embodiments described are only examples and that various modifications can be made within the scope of the invention as defined in the appended claims.

What is claimed is:

1. A method of producing drift detectors with or without epitaxial layers, the method comprising:
depositing at least one dielectric film deposited at temperatures no higher than 350 degrees Centigrade.

2. The method of claim 1 wherein a sum of a product of the exponential of the inverse negative of the temperature in degrees Kelvin and the square root of the time in seconds during which the temperature is applied during deposition is no greater than 220.

3. The method of claim 1, in which a product of the exponential of the inverse temperature in degrees Kelvin and the square root of the time in seconds during which the temperature is applied over every one of the steps in the process of fabrication is no greater than 100.

4. The method of claim 1, further comprising depositing a single high-quality dielectric film at temperatures higher than 350 degrees Centigrade.

5. The method of claim 4, wherein the deposition of the single high-quality dielectric film is performed prior to deposition of the at least one other dielectric film deposited at temperatures no higher than 350 degrees Centigrade.

6. The method of claim 4, wherein a sum of a product of the exponential of the inverse negative of the temperature in degrees Kelvin and the square root of the time in seconds during which the temperature is applied during deposition is no greater than 220.

7. The method of claim 4, in which a product of the exponential of the inverse temperature in degrees Kelvin and the square root of the time in seconds during which the temperature is applied over every one of the steps in the process of fabrication is no greater than 100.

8. A Compton camera employing drift detectors fabricated by a process that includes depositing at least one dielectric film deposited at temperatures no higher than 350 degrees Centigrade.

9. The Compton camera of claim 8, wherein the drift detector fabrication process also includes depositing a single high-quality dielectric film at temperatures higher than 350 degrees Centigrade.

10. The Compton camera of claim 8, wherein a sum of a product of the exponential of the inverse negative of the temperature in degrees Kelvin and the square root of the time in seconds during which the temperature is applied during deposition is no greater than 220.

11. The Compton camera of claim 8, in which a product of the exponential of the inverse temperature in degrees Kelvin and the square root of the time in seconds during which the temperature is applied over every one of the steps in the process of fabrication is no greater than 100.

12. The Compton camera of claim 8, configured to provide electron-tracking capability.

13. The Compton camera of claim 12, including a scattering medium and an absorbing medium that are separated by less than 15 cm.
